(19) United States
(12) Patent Application Publication
(10) Pub. No.: US 2008/0079109 A1
(43) Pub. Date: Apr. 3, 2008

(54) Thermoelectric device and method for making the same

(76) Inventor: Chin-Kuang Luo, Taichung City (TW)

Correspondence Address: TROP PRUNER & HU, PC, 1616 S. VOSS ROAD, SUITE 750, HOUSTON, TX, 77057-2631, US

(21) Appl. No.: 11/529,833

(22) Filed: Sep. 29, 2006

(51) Int. Cl. H01L 31/058; H01L 21/00

(52) U.S. Cl. 257/470; 438/54; 257/E27.008

(57) ABSTRACT

A thermoelectric device includes: a first insulator substrate; a plurality of first pads of copper foil attached to the first insulator substrate; a second insulator substrate; a plurality of second pads of copper foil attached to the second insulator substrate; and a plurality of alternately disposed p-type and n-type semiconductor elements disposed between the first and second insulator substrates. Each of the p-type and n-type semiconductor elements has two opposite ends that are respectively bonded to a respective one of the first pads of copper foil and a respective one of the second pads of copper foil through a copper brazing material.

### BACKGROUND OF THE INVENTION

1. Field of the Invention

This invention relates to a thermoelectric device and a method for making the same, more particularly to a thermoelectric device having first and second insulator substrates bonded to p-type and n-type semiconductor elements through copper foil and a copper brazing material.

2. Description of the Related Art

It is known that conventional thermoelectric devices are made by bonding p-type and n-type semiconductor elements to a pair of oppositely disposed insulator substrates through a Sn-based alloy solder. However, since Sn-based alloy solder has a relatively low melting temperature, the conventional thermoelectric devices can only be operated under a low temperature environment.

### SUMMARY OF THE INVENTION

Therefore, the object of the present invention is to provide a thermoelectric device and a method for making the same that can overcome the aforesaid drawback of the prior art.

According to one aspect of this invention, there is provided a thermoelectric device that comprises: a first insulator substrate having an inner surface; a plurality of first pads of copper foil attached to the inner surface of the first insulator substrate; a second insulator substrate having an inner surface facing toward the inner surface of the first insulator substrate; a plurality of second pads of copper foil attached to the inner surface of the second insulator substrate; and a plurality of alternately disposed p-type and n-type semiconductor elements disposed between the first and second insulator substrates. Each of the p-type and n-type semiconductor elements has two opposite ends that are respectively bonded to a respective one of the first pads of copper foil and a respective one of the second pads of copper foil through a copper brazing material.

According to another aspect of this invention, there is provided a method for making the thermoelectric device. The method comprises: (a) attaching a plurality of first pads of copper foil to a first insulator substrate; (b) attaching a plurality of second pads of copper foil to a second insulator substrate; (c) applying a copper brazing material to each of the first and second pads of copper foil; (d) stacking one side of a jig on the first insulator substrate such that each of jig holes in the jig is registered with a respective one of the first pads of copper foil; (e) disposing alternately a plurality of p-type and n-type semiconductor elements in the jig holes such that each of the p-type and n-type semiconductor elements is in contact with a respective one of the first pads of copper foil; (f) stacking the second insulator substrate on an opposite side of the jig such that each of the p-type and n-type semiconductor elements is in contact with a respective one of the second pads of copper foil; and (g) melting and then solidifying the copper brazing material on the first and second pads of copper foil so as to permit bonding of each of the p-type and n-type semiconductor elements to the respective one of the first pads of copper foil and the respective one of the second pads of copper foil.

According to yet another aspect of this invention, there is provided a method for making the thermoelectric device. The method comprises: (a) attaching a plurality of first pads of copper foil to a first insulator substrate; (b) attaching a plurality of second pads of copper foil to a second insulator substrate; (c) applying a copper brazing material to each of the first and second pads of copper foil; (d) stacking one side of a jig on the first insulator substrate such that each of jig holes in the jig is registered with a respective one of the first pads of copper foil; (e) disposing alternately a plurality of p-type and n-type semiconductor elements in the jig holes such that each of the p-type and n-type semiconductor elements is in contact with a respective one of the first pads of copper foil; (f) melting and then solidifying the copper brazing material on the first pads of copper foil so as to permit bonding of each of the p-type and n-type semiconductor elements to the respective one of the first pads of copper foil; (g) removing the jig from the first insulator substrate; (h) stacking the second insulator substrate on the p-type and n-type semiconductor elements such that each of the p-type and n-type semiconductor elements is in contact with a respective one of the second pads of copper foil; and (i) melting and then solidifying the copper brazing material on the second pads of copper foil so as to permit bonding of each of the p-type and n-type semiconductor elements to the respective one of the second pads of copper foil.

### BRIEF DESCRIPTION OF THE DRAWING

Other features and advantages of the present invention will become apparent in the following detailed description of the preferred embodiments of this invention, with reference to the accompanying drawing, in which:

FIG. 1 is a schematic view of the first preferred embodiment of a thermoelectric device according to this invention;

FIGS. 2 to 7 are schematic views to illustrate consecutive steps of a method for making the first preferred embodiment;

FIG. 8 is a schematic view of the second preferred embodiment of the thermoelectric device according to this invention;

FIGS. 9 to 15 are schematic views to illustrate consecutive steps of the method for making the second preferred embodiment; and

FIG. 16 is a schematic view of the second preferred embodiment connected to a power supply.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

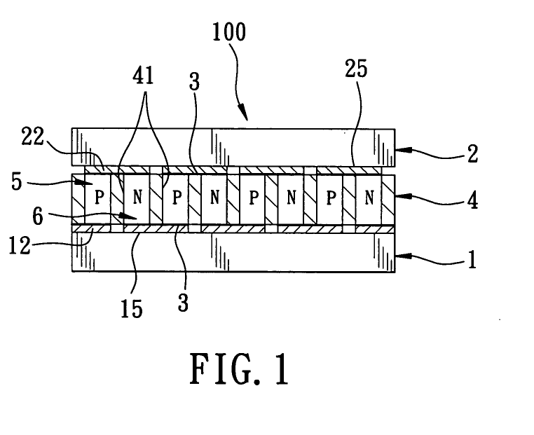

FIG. 1 illustrates the first preferred embodiment of a thermoelectric device 100 according to this invention. The thermoelectric device 100 includes: a first insulator substrate 1 having an inner surface 15; a plurality of first pads 12 of copper foil attached to the inner surface 15 of the first insulator substrate 1; a second insulator substrate 2 having an inner surface 25 facing toward the inner surface 15 of the first insulator substrate 1; a plurality of second pads 22 of copper foil attached to the inner surface 25 of the second insulator substrate 2; and a plurality of alternately disposed p-type and n-type semiconductor elements 5, 6 disposed between the first and second insulator substrates 1, 2. Each of the p-type and n-type semiconductor elements 5, 6 has two opposite ends that are respectively bonded to a respective one of the first pads 12 of copper foil and a respective one of the second pads 22 of copper foil through a copper brazing material 3.

In this embodiment, the copper brazing material 3 has a melting temperature less than that of the copper foil which has a melting temperature of about 1200° C. Preferably, the copper brazing material 3 has a melting temperature ranging from 700 to 800° C. Preferably, each of the first and second pads 12, 22 of copper foil has a layer thickness ranging from 0.2 to 0.5 mm.

Preferably, each of the first and second insulator substrates 1, 2 is made from a ceramic material.

In this embodiment, a jig 4 is used for mounting of the p-type and n-type semiconductor elements 5, 6, and has an array of jig holes 41. Each of the p-type and n-type semiconductor elements 5, 6 is disposed in a respective one of the jig holes 41. The jig 4 is preferably made from a ceramic material.

The first pads 12 of copper foil on the first insulator substrate 1 and the second pads 22 of copper foil on the second insulator substrate 2 serve respectively as first and second electrodes of the thermoelectric device 100 which are adapted to be connected to a power source (not shown). The first and second pads 12, 22 of copper foil cooperate with the p-type and n-type semiconductor elements 5, 6 to form a series of Peltier junctions, and the p-type and n-type semiconductor elements 5, 6 are assembled together in series electrically and in parallel thermally such that the first insulator 1 serves as a cold end that absorbs heat from a heat source (not shown), and that the second insulator substrate 2 serves as a hot end that releases heat from the cold end into ambient environment. Since the copper brazing material 3 has a relatively high melting temperature, the thermoelectric device 100 of this invention can endure a relatively high temperature resulting from the heat source.

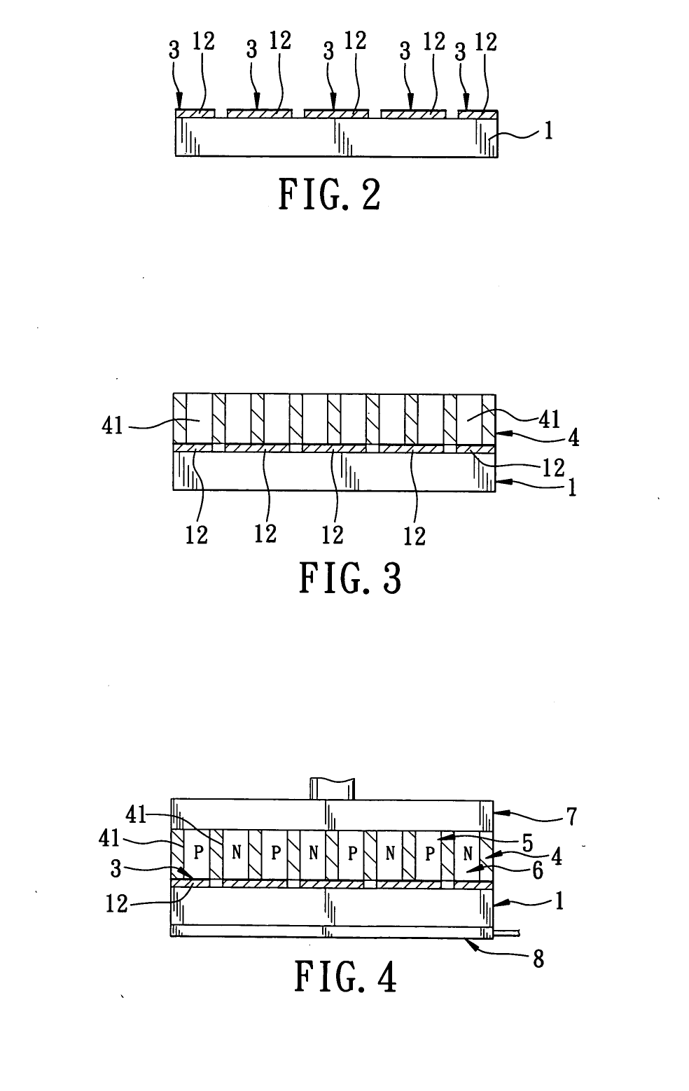

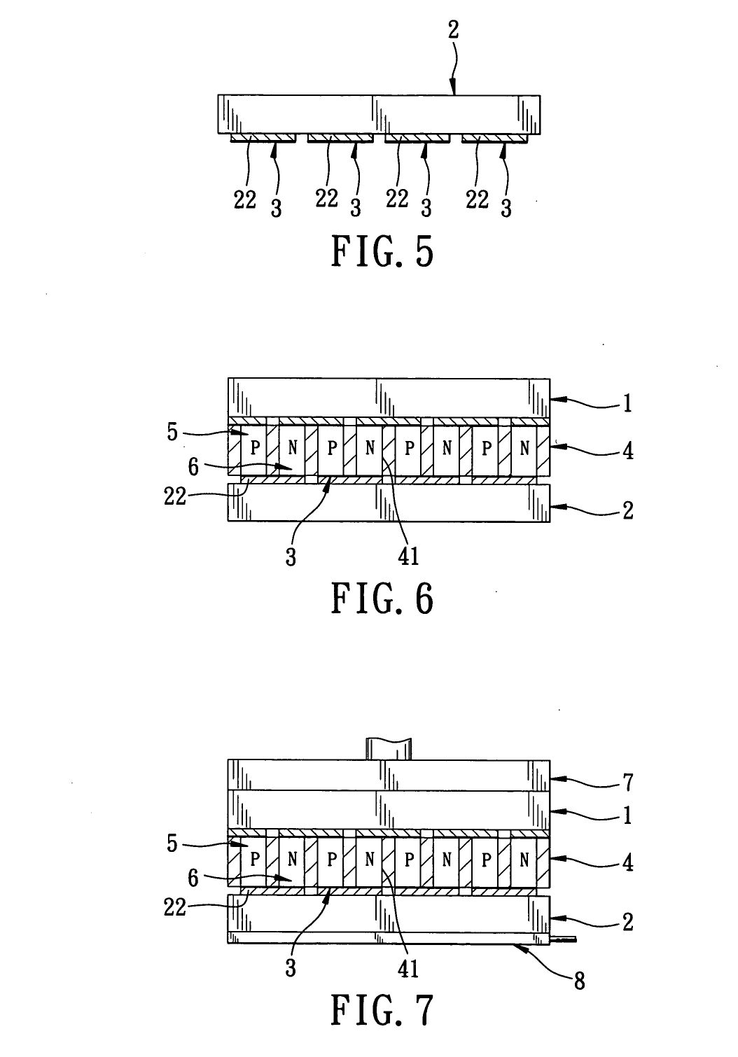

FIGS. 2 to 7 illustrate consecutive steps of a method for making the thermoelectric device 100 of the first preferred embodiment. The method includes the steps of: (a) attaching the first pads 12 of copper foil to the first insulator substrate 1 (see FIG. 2); (b) attaching the second pads 22 of copper foil to the second insulator substrate 2 (see FIG. 5); (c) applying the copper brazing material 3 to each of the first and second pads 12, 22 of copper foil (see FIGS. 2 and 5); (d) stacking one side of the jig 4 on the first insulator substrate 1 such that each of the jig holes 41 in the jig 4 is registered with the respective one of the first pads 12 of copper foil (see FIG. 3); (e) disposing alternately the p-type and n-type semiconductor elements 5, 6 in the jig holes 41 such that each of the p-type and n-type semiconductor elements 5, 6 is in contact with the respective one of the first pads 12 of copper foil (see FIG. 4); (f) stacking the second insulator substrate 2 on an opposite side of the jig 4 such that each of the p-type and n-type semiconductor elements 5, 6 is in contact with the respective one of the second pads 22 of copper foil (see FIG. 6); and (g) melting and then solidifying the copper brazing material 3 on the first and second pads 12, 22 of copper foil so as to permit bonding of each of the p-type and n-type semiconductor elements 5, 6 to the respective one of the first pads 12 of copper foil and the respective one of the second pads 22 of copper foil (see FIG. 7).

The bonding of each of the p-type and n-type semiconductor elements 5, 6 to the respective one of the first and second pads 12, 22 of copper foil in step (g) is conducted by using a pressing member 7 that is attached to the first insulator substrate 1 to press the jig 4 and the p-type and n-type semiconductor elements 5, 6 against the first and second insulator substrates 1, 2, and a heater 8 that is attached to the second insulator substrate 2 to melt the copper brazing material 3. The pressing member 7 and the heater 8 are subsequently removed thereafter.

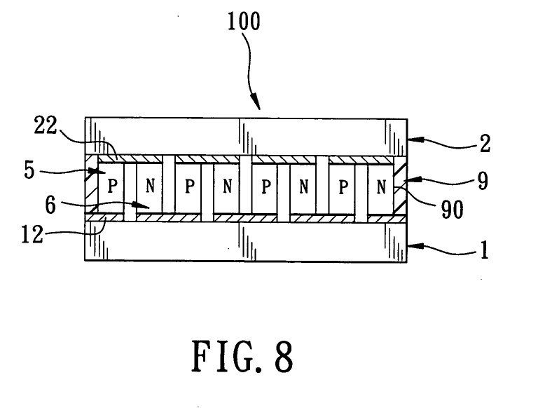

FIG. 8 illustrates the second preferred embodiment of the thermoelectric device 100 according to this invention. The second preferred embodiment differs from the previous embodiment in that the jig 4 is dispensed with and that an enclosure 9 is provided thereon. The enclosure 9, which is preferably made from silicone rubber, is disposed between the first and second insulator substrates 1, 2, and encloses sealingly the p-type and n-type semiconductor elements 5, 6. The enclosure 9 defines an enclosing space 90 receiving the p-type and n-type semiconductor elements 5, 6 therein. The enclosing space 90 is vacuumed so as to prevent undesired heat conduction between the first and second insulator substrates 1, 2 through air inside the enclosing space 90.

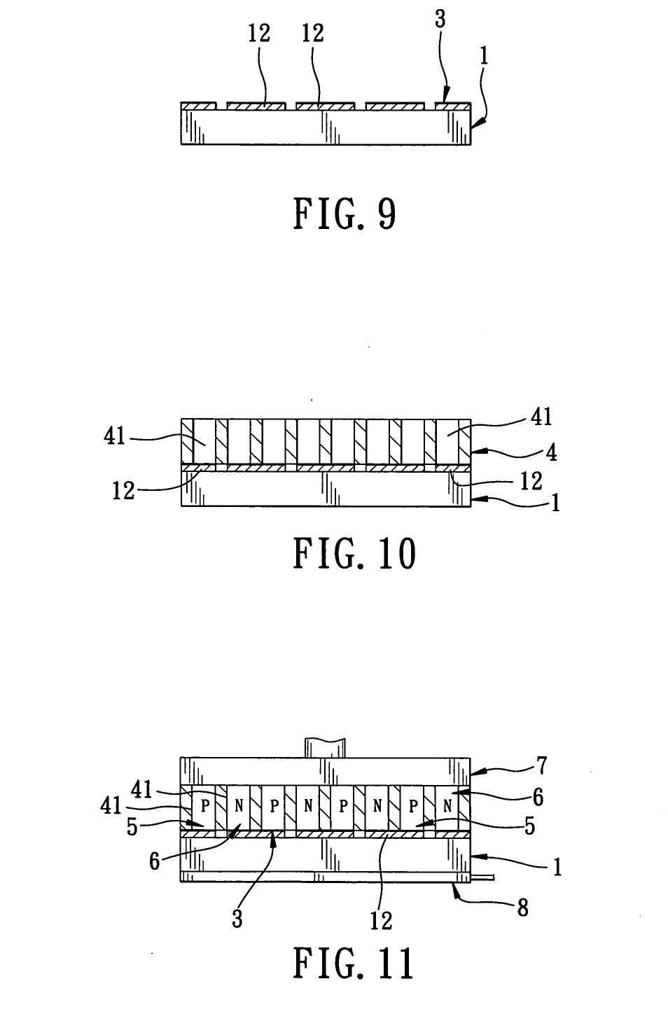

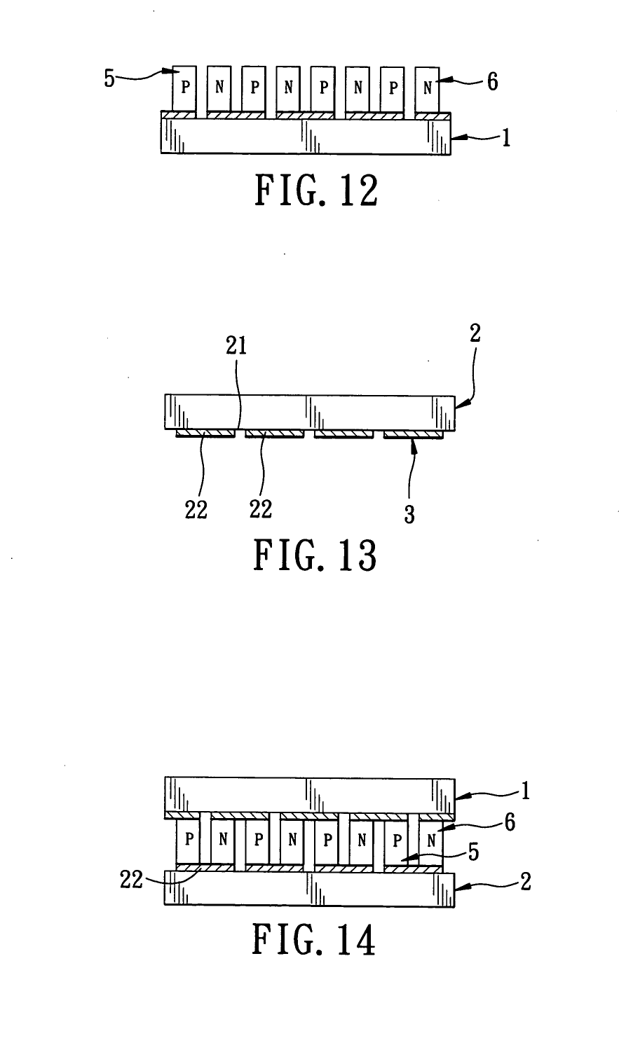

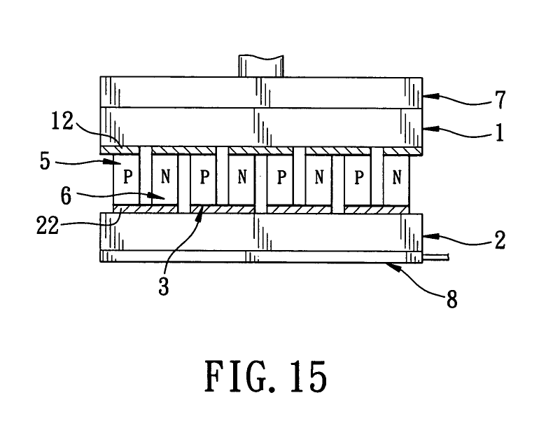

FIGS. 9 to 15 illustrate consecutive steps of a method for making the thermoelectric device 100 of the second preferred embodiment. The method includes the steps of: (a) attaching the first pads 12 of copper foil to the first insulator substrate 1 (see FIG. 9); (b) attaching the second pads 22 of copper foil to the second insulator substrate 2 (see FIG. 13); (c) applying the copper brazing material 3 to each of the first and second pads 12, 22 of copper foil (see FIGS. 9 and 13); (d) stacking one side of the jig 4 on the first insulator substrate 1 such that each of the jig holes 41 in the jig 4 is registered with a respective one of the first pads 12 of copper foil (see FIG. 10); (e) disposing alternately the p-type and n-type semiconductor elements 5, 6 in the jig holes 41 such that each of the p-type and n-type semiconductor elements 5, 6 is in contact with the respective one of the first pads 12 of copper foil (see FIG. 11); (f) melting and then solidifying the copper brazing material 3 on the first pads 12 of copper foil using the pressing member 7 and the heater 8 so as to permit bonding of each of the p-type and n-type semiconductor elements 5, 6 to the respective one of the first pads 12 of copper foil; (g) removing the jig 4 from the first insulator substrate 1 (see FIG. 12); (h) stacking the second insulator substrate 2 on the p-type and n-type semiconductor elements 5, 6 such that each of the p-type and n-type semiconductor elements 5, 6 is in contact with the respective one of the second pads 22 of copper foil (se FIG. 14); (i) melting and then solidifying the copper brazing material 3 on the second pads 22 of copper foil using the pressing member 7 and the heater 8 so as to permit bonding of each of the p-type and n-type semiconductor elements 5, 6 to the respective one of the second pads 22 of copper foil (see FIG. 15); (j) enclosing the p-type and n-type semiconductor elements 5, 6 with the enclosure 9; and (k) vacuuming the enclosing space 90. The pressing member 7 and the heater 8 are subsequently removed after steps (f) and (i).

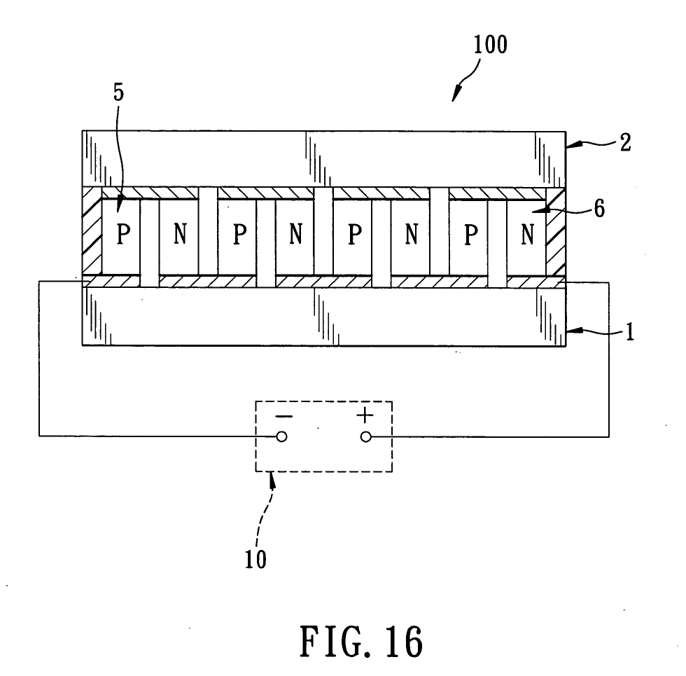

FIG. 16 shows the electrical connection between the thermoelectric device 100 of the second preferred embodiment and a power supply 10. The electrical connection renders the first insulator substrate 1 to serve as the cold end of the Peltier junctions, and the second insulator substrate 2 to serve as the hot end of the Peltier junctions.

By using the copper brazing material 3 to bond the p-type and n-type semiconductor elements 5, 6 to the first and second pads 12, 22 of copper foil, the thermoelectric device 100 of this invention can be operated under a relatively high temperature environment as compared to the aforesaid conventional thermoelectric devices.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A thermoelectric device comprising:
a first insulator substrate having an inner surface;
a plurality of first pads of copper foil attached to said inner surface of said first insulator substrate;
a second insulator substrate having an inner surface facing toward said inner surface of said first insulator substrate;
a plurality of second pads of copper foil attached to said inner surface of said second insulator substrate; and
a plurality of alternately disposed p-type and n-type semiconductor elements disposed between said first and second insulator substrates, each of said p-type and n-type semiconductor elements having two opposite ends that are respectively bonded to a respective one of said first pads of copper foil and a respective one of said second pads of copper foil through a copper brazing material.

2. The thermoelectric device of claim 1, wherein said copper brazing material has a melting temperature less than that of said copper foil.

3. The thermoelectric device of claim 1, wherein said copper brazing material has a melting temperature ranging from 700 to 800° C.

4. The thermoelectric device of claim 1, wherein each of said first and second pads of copper foil has a layer thickness ranging from 0.2 to 0.5 mm.

5. The thermoelectric device of claim 1, wherein each of said first and second insulator substrates is made from a ceramic material.

6. The thermoelectric device of claim 1, further comprising a jig having an array of jig holes, each of said p-type and n-type semiconductor elements being disposed in a respective one of said jig holes.

7. The thermoelectric device of claim 6, wherein said jig is made from a ceramic material.

8. The thermoelectric device of claim 1, further comprising an enclosure disposed between said first and second insulator substrates and enclosing sealingly said p-type and n-type semiconductor elements.

9. The thermoelectric device of claim 8, wherein said enclosure defines an enclosing space receiving said p-type and n-type semiconductor elements therein, said enclosing space being vacuumed.

10. The thermoelectric device of claim 8, wherein said enclosure is made from silicone rubber.

11. A method for making a thermoelectric device, comprising:
(a) attaching a plurality of first pads of copper foil to a first insulator substrate;
(b) attaching a plurality of second pads of copper foil to a second insulator substrate;
(c) applying a copper brazing material to each of the first and second pads of copper foil;
(d) stacking one side of a jig on the first insulator substrate such that each of jig holes in the jig is registered with a respective one of the first pads of copper foil;
(e) disposing alternately a plurality of p-type and n-type semiconductor elements in the jig holes such that each of the p-type and n-type semiconductor elements is in contact with a respective one of the first pads of copper foil;
(f) stacking the second insulator substrate on an opposite side of the jig such that each of the p-type and n-type semiconductor elements is in contact with a respective one of the second pads of copper foil; and
(g) melting and then solidifying the copper brazing material on the first and second pads of copper foil so as to permit bonding of each of the p-type and n-type semiconductor elements to the respective one of the first pads of copper foil and the respective one of the second pads of copper foil.

12. The method of claim 11, further comprising pressing the jig and the p-type and n-type semiconductor elements against the first and second insulator substrates during step (g).

13. The method of claim 11, wherein the copper brazing material has a melting temperature less than that of the copper foil.

14. The method of claim 14, wherein the copper brazing material has a melting temperature ranging from 700 to 800° C.

15. The method of claim 11, wherein each of the first and second insulator substrates is made from a ceramic material.

16. A method for making a thermoelectric device, comprising:
(a) attaching a plurality of first pads of copper foil to a first insulator substrate;
(b) attaching a plurality of second pads of copper foil to a second insulator substrate;
(c) applying a copper brazing material to each of the first and second pads of copper foil;
(d) stacking one side of a jig on the first insulator substrate such that each of jig holes in the jig is registered with a respective one of the first pads of copper foil;
(e) disposing alternately a plurality of p-type and n-type semiconductor elements in the jig holes such that each of the p-type and n-type semiconductor elements is in contact with a respective one of the first pads of copper foil;
(f) melting and then solidifying the copper brazing material on the first pads of copper foil so as to permit bonding of each of the p-type and n-type semiconductor elements to the respective one of the first pads of copper foil;
(g) removing the jig from the first insulator substrate;
(h) stacking the second insulator substrate on the p-type and n-type semiconductor elements such that each of the p-type and n-type semiconductor elements is in contact with a respective one of the second pads of copper foil; and
(i) melting and then solidifying the copper brazing material on the second pads of copper foil so as to permit bonding of each of the p-type and n-type semiconductor elements to the respective one of the second pads of copper foil.

17. The method of claim 16, wherein the copper brazing material has a melting temperature ranging from 700 to 800° C.

18. The method of claim 16, wherein each of the first and second insulator substrates is made from a ceramic material.

19. The method of claim 16, further comprising enclosing the p-type and n-type semiconductor elements with an enclosure after step (i) such that the p-type and n-type semiconductor elements are enclosed sealingly in an enclosing space in the enclosure; and vacuuming the enclosing space.

20. The method of claim 19, wherein the enclosure is made from silicone rubber.
